(19) United States
(12) Patent Application Publication
(10) Pub. No.: US 2008/0108505 A1
(43) Pub. Date: May 8, 2008

(54) Resistive Type Current-Limiting Apparatus with High-Tc Superconductor Track Formed in a Strip

(76) Inventors: Hans-Peter Kramer, Erlangen (DE); Wolfgang Schmidt, Erlangen (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/664,613

(22) PCT Filed: Sep. 27, 2005
(86) PCT No.: PCT/EP05/54844

§ 371 Date: Apr. 4, 2007

(30) Foreign Application Priority Data
Oct. 4, 2004 (DE) 10 2004 048 648.4

(51) Int. Cl. H01L 39/00

(52) U.S. Cl. 505/193

(57) ABSTRACT

A strip-shaped superconductor has a conductor structure containing at least one metallic substrate strip, a layer made of oxidic high T_{c} superconducting material of the AB₂Cu₃OX type; an oxidic buffer layer, which is arranged therebetween and which has adapted crystalline dimensions, and; a normal-conductive top layer that is applied to the superconductive layer. The buffer layer should be formed so that a transition resistance of no greater than 10⁻³ Ωcm² is formed at least in partial areas between the superconductive layer and the substrate strip. For example, suitable materials are of the La—Mn—O or Sr—Ru—O or La—Ni—O or In—Sn—O type.

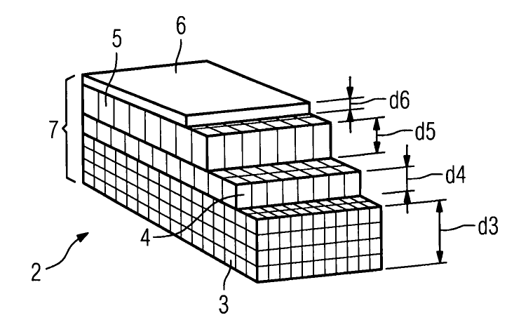

### CROSS REFERENCE TO RELATED APPLICATIONS

This application is based on and hereby claims priority to German Application No. 10 2004 048 648.4 filed on Oct. 4, 2004, the contents of which are hereby incorporated by reference.

### BACKGROUND

A resistive superconducting current-limiting apparatus may have a conductor track composed of a superconductor in the form of a strip, whose conductor structure contains at least one substrate strip composed of a normally conductive substrate metal, a superconducting layer composed of an oxidic high-T_{c} superconductor material of the AB₂Cu₃Oₓ type, with A being at least one rare earth metal including yttrium, and B being at least one alkaline earth metal, a buffer layer, which is arranged between them and is composed of an oxidic buffer material with matched crystalline dimensions, as well as a covering layer which is applied to the superconducting layer and is composed of a normally conductive covering layer material. An example of such a current-limiting apparatus is disclosed in DE 199 09 266 A1.

Superconducting metal-oxide compounds with high critical temperatures T_{c} of above 77 K have been known since 1986, which are therefore referred to as high-T_{c} superconductor materials, or HTS materials, and, in particular, allow a liquid-nitrogen (LN₂) cooling technique. Metal-oxide compounds such as these include in particular cuprates based on specific substance systems, for example of the AB₂Cu₃Ox type, with A being at least one rare earth metal including yttrium, and B being at least one alkaline earth metal. The main representative of this substance system of the so-called 1-2-3-HTS type is so-called YBCO (Y₁Ba₂Cu₃Oₓ where 6.5≦x≦7).

The aim is to deposit this known HTS material on different substrates for different purposes, in which case the general aim is to achieve a superconductor material with as high a phase purity as possible. In particular, metallic substrates are therefore provided for conductor applications (see, for example, EP 0 292 959 A1).

With a corresponding conductor structure, the HTS material is in general not deposited directly on a mount strip which is used as a substrate; instead, this substrate strip is first of all covered with at least one thin intermediate layer, which is also referred to as a buffer layer. This buffer layer has a thickness in the order of magnitude of 1 μm and is intended on the one hand to prevent diffusion of metal atoms from the substrate into the HTS material, which could result in the superconducting characteristics becoming poorer. On the other hand, the buffer layer is intended to allow a textured structure for the HTS material. Corresponding buffer layers are in general composed of oxides of metals such as zirconium, cerium, yttrium, aluminum, strontium or magnesium, or mixed crystals with a plurality of these metals, and are thus electrically insulating. In a corresponding electrically conductive conductor track, a problem occurs as soon as the superconducting material changes to the normally conductive state (so-called “quenching”). In this state, the superconductor first of all becomes resistive in places, and thus assumes a resistance R, for example by being heated above the critical temperature T_{c} of its superconductor material (at so-called “hot spots” or partial quenching areas), and is generally heated further, so that the layer can burn through.

Because of this problem, it is known for an additional metallic covering layer composed of an electrically highly conductive material which is compatible with the HTS material, such as gold or silver, to be applied as a shunt to prevent burning through, directly on the HTS line layer. The HTS material thus makes an electrically conductive contact over an area with the metallic covering layer (see DE 44 34 819 C).

Because of the hot spots or partial quenching areas which also occur with shunts, the voltage is distributed non-uniformly along the superconductor layer. In contrast, the voltage U which is applied to the ends is dropped uniformly over the entire length of the substrate strip to which the superconducting layer is applied, or it is at an undefined intermediate potential, if the ends are isolated from the applied voltage. In some circumstances, this can result in voltage differences from the conductor track via the buffer layer to the substrate. Because this layer is thin, this necessarily leads to electrical flashovers, and thus to dysfunction of the buffer layer, and possibly of the superconducting layer, at some points. Voltages in the order of magnitude of 20 to 100 volts are typically sufficient for a flashover for buffer layer thicknesses of 1 μm. A corresponding problem occurs in particular when it is intended to use resistive current-limiting apparatuses with corresponding conductor strips. This is because the transition from the superconducting state to the normally conductive state is utilized in apparatus such as this for current limiting in the event of a short circuit. In this case, it is not possible without problems to make the buffer layer sufficiently voltage-resistant for the normal operating voltages for such apparatus in the kV range.

A superconductor in the form of a strip and with an appropriate structure is used for the current-limiting apparatus disclosed in the initially cited DE-A1 document. The risk of electrical flashovers across the buffer layer that has been mentioned exists with this structure.

### SUMMARY

An aspect is to preclude this risk of an electrical flashover on quenching in the event of current limiting for a resistive superconducting current-limiting apparatus having the features mentioned initially.

Accordingly, in the current-limiting apparatus having the features mentioned initially the at least one buffer layer is intended to be formed in such a manner that a contact resistance of at most 10⁻³ Ω·cm², preferably at most 10⁻⁵ Q·cm² is formed, at least in subareas, between the superconducting layer and the substrate strip.

The specific problems that have been mentioned for current-limiting apparatuses can be solved by specific buffer-layer materials. It has been found that the desired potential equalization can be ensured by the magnitude according to the invention of the contact resistance related to the unit area (at the superconducting material operating temperature of about 77 K). The “contact resistance” which is used as the physical variable in this case is quoted in Ohm·cm² (Ω·cm²) or in Ohm·m². It is also widely referred to as the “contact surface resistance” (see for example “Applied Physics Letters”, volume 52, No. 4, 25 Jan. 1988, pages 331 to 333 or EP 0 315 460 A2). This contact resistance in this case represents the electrical (pure) resistance R (measured in Ω) of a connection with an area of 1 cm² or 1 m² contact area A between two in particular electrically conductive parts. The product R·A is independent of the contact area. This denotes the quality of an electrical connection over an area between two connected parts, for example in the case of a soldered joint between two conductors, or between the contact pieces of the contacts in a switch.

The advantages associated with the embodiment of the current-limiting apparatus are, accordingly, that the metallic substrate strip and the normally conductive covering layer, and hence also the superconducting layer which is conductively connected to it, across the at least one buffer layer, can be brought into electrical contact with one another, at least in subareas, and can be thus at a common electrical potential, even in the case of a quench. This suppresses any flashover across a buffer layer as can occur in the known current-limiting apparatuses.

In particular, the following measures can also be provided individually, or else in conjunction, for the proposed current-limiting apparatus:

A material which has a mean resistivity of at most 5000 μΩ·cm, preferably of at most 500 μΩ·cm can thus preferably be chosen for the material of the buffer layer.

If an oxidic compound of the La—Mn—O, Sr—Ru—O, La—Ni—O or In—Sn—O type is chosen for the material of the buffer layer, then the magnitude of the contact resistance can be complied with without any problems.

The conductor structure of the superconductor is, of course, not restricted to the stated four layers. A layer system composed of a plurality of individual layers can thus in each case also be provided for the covering layer and/or for the buffer layer.

### BRIEF DESCRIPTION OF THE DRAWINGS

These and other objects and advantages will become more apparent and more readily appreciated from the following description of one preferred exemplary embodiment of a current-limiting apparatus, taken in conjunction with the accompanying drawing:

The FIGURE is a highly schematic perspective view of a configuration of a YBCO strip conductor of the current-limiting apparatus.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

The strip conductor that is indicated in the FIGURE and is annotated 2 in general is based on embodiments of so-called YBCO strip conductors or “YBCO Coated Conductors” that are known per se. In the figure, 3 denotes a substrate strip composed of a normally conductive substrate metal of thickness d3, 4 denotes at least one buffer layer applied to it and composed of a particular oxidic buffer material of thickness d4, 5 denotes at least one HTS layer composed of YBCO of thickness d5, 6 denotes at least one covering layer composed of a normally conductive covering metal of thickness d6 as a protective and/or contact layer, and 7 shows the conductor structure formed from these four parts.

In this case, these parts can be formed as follows:
a metallic substrate strip 3 composed of nickel, nickel alloys or stainless steel with a thickness d3 of about 50 to 250 μm,
at least one buffer layer or a buffer layer system composed of one or more individual layers of oxides to be chosen particularly with a thickness d4 of about 0.1 μm to 1.5 mm,
at least one HTS layer 5 composed of YBCO with a thickness d5 of between about 0.3 and 3 μm, and
at least one metallic covering layer 6 composed of silver, gold or copper, with a thickness d6 of between 0.1 and 1 μm. In this case, the covering layer can also be composed of a plurality of layers of metallic material, if appropriate of different metals.

A corresponding strip conductor has a width of a few millimeters to a few centimeters. Its superconducting current carrying capability is governed by the YBCO layer 5, that is to say by its critical current density, while the thermal, mechanical and normally conductive characteristics are dominated by the substrate strip 3, because of the greater thickness d3. In this case, the substrate strip together with the buffer layer forms a substrate for virtually monocrystalline growth of the YBCO. The substrate strip material and the buffer layer material must not differ too greatly from YBCO in terms of the thermal coefficients of expansion and their crystallographic lattice constants. The better the match, the higher is the crack-free layer thickness, and the better the crystallinity of the YBCO. Furthermore, for high critical current densities in the MA/cm² range, it is desirable for the crystal axes in adjacent crystallites to be aligned as parallel as possible. This requires just such an alignment at least in the uppermost buffer layer in order that the YBCO can be growth heteroepitaxially. Such virtually monocrystalline flexible substrate buffer systems are preferably prepared using three processes:
so-called “Ion Beam Assisted Deposition (IBAD)” of generally YSZ or MgO on untextured metal strips,
so-called “Inclined Substrate Deposition (ISD)” of YSZ or MgO on untextured metal strips,
so-called “Rolling Assisted Biaxially Textured Substrates (RABiTS)”, that is to say substrates provided with cube-type texturing by rolling and heat treatment, with a heteroepitaxial buffer system.

The functional layers 4 to 6 to be deposited on the substrate strip are produced in a manner known per se by vacuum coating processes (PVD), chemical deposition from the gas phase (CVD) or from chemical solutions (CSD).

Comparatively thin intermediate layers, which are formed during the production of the structure or during the deposition of the individual layers in particular by diffusion and/or reaction processes, can, of course, be provided at the interface between the individual layers of the structure 7, as well.

In comparison to the ceramic plate conductors which are known for YBCO thin-film current limiting apparatuses, the substrate strip 3 in the case of strip conductors of the type described above is electrically conductive, that is to say it can carry the limited current and can act as a shunt. However, with the conductor structure 7 shown in the figure, the HTS layer 5 and the substrate strip 3 would normally be insulated from one another, if the buffer materials for known current-limiting apparatus, such as CeO₂ or YSZ, are chosen. As soon as the current-limiting apparatus changes to its limiting state, that is to say becomes normally conductive and builds up a voltage along the conductor track, the breakdown field strength of the known buffer layer materials, which is in the order of magnitude of 100 kV/mm=10 V/0.1 μm, will quickly be exceeded. This means that the buffer layer 4 would then flash over in an uncontrolled manner. Thus, a buffer-layer material which can be chosen specifically is advantageous for the use of YBCO strip conductors in current-limiting apparatuses. In this case, of course, the aspects mentioned above of adequate matching of the crystalline dimensions of the HTS material that is used and of the buffer-layer material must also be taken into account.

On the basis of the further aspect of potential equalization between the superconducting layer 5, and hence also the covering layer 6 on the one hand, and the substrate strip 3 on the other hand, an oxidic material is chosen for the at least one buffer layer 4, such that a contact resistance is formed between the superconducting layer 5 and the substrate strip 3 at least at individual island-like points, for example, preferably over the entire common area extent of at most 10⁻³ Ω·cm², preferably of at most 10⁻⁵ Q·cm². The desired potential equalization can then be achieved while complying with these values.

In particular, a material which has a mean resistivity of at most 5000 μΩ·cm, preferably of at most 500 μΩ·cm, can be chosen for the buffer layer 4. This is because it has been found that the contact resistances mentioned above can be achieved using oxidic materials which satisfy this condition, thus allowing the desired potential equalization.

Examples of materials which satisfy all of the preconditions that have been mentioned are oxidic materials which are known per se of the La—Mn—O, Sr—Ru—O, La—Ni—O or In—Sn—O type (the so-called “ITO”).

The above exemplary embodiment has been based on YBCO as the HTS material for the superconducting layer 5. Other HTS materials of the so-called 1-2-3 type can, of course, also be used with other rare earth metals and/or other alkaline earth metals. The individual components of these materials may also be partially substituted in a manner known per se by further/other components.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-6. (canceled)

7. A resistive superconducting current-limiting apparatus with a conductor track, comprising:
a substrate strip formed of a normally conductive substrate metal;
a superconducting layer formed of an oxidic high-T_{c} superconductor material of AB₂Cu₃Oₓ where A represents at least one element selected from the group consisting of yttrium and other rare earth metals, and B represents at least one alkaline earth metal;
a buffer layer, arranged between said substrate strip and said superconducting layer, formed of an oxidic buffer material with matched crystalline dimensions, said at least one buffer layer having a contact resistance, at least in subareas, of at most 10⁻³ Ω·cm²; and
a covering layer applied to said superconducting layer and formed of a normally conductive covering layer material.

8. The current-limiting apparatus as claimed in claim 7, wherein the contact resistance of said buffer layer, at least in the subareas, is at most 10⁻⁵ Ω·cm².

9. The current-limiting apparatus as claimed in claim 8, wherein the oxidic buffer material of said buffer layer is selected from the group consisting of La—Mn—O, Sr—Ru—O, La—Ni—O and In—Sn—O.

10. The current-limiting apparatus as claimed in claim 9, wherein the oxidic buffer material of said buffer layer has a mean resistivity of at most 5000 μΩ·cm.

11. The current-limiting apparatus as claimed in claim 10, wherein the oxidic buffer material of said buffer layer has a mean resistivity of at most 500 μΩ·cm.

12. The current-limiting apparatus as claimed in claim 10, wherein said covering layer is formed of a plurality of layers of metallic material.

13. The current limiting apparatus as claimed in claim 11, wherein said buffer layer is formed of a plurality of layers of different oxidic materials.
